(19) United States
(12) Patent Application Publication
(10) Pub. No.: US 2008/0273568 A1
(43) Pub. Date: Nov. 6, 2008

(54) Beam combiner for a multicolor laser display

(75) Inventors: Roland Schulz, Regensburg (DE); Thomas Schwarz, Regensburg (DE)

Correspondence Address: COHEN PONTANI LIEBERMAN & PAVANE LLP, Suite 1210, 551 Fifth Avenue, New York, NY, 10176, US

(73) Assignee: OSRAM Opto Semiconductors GmbH, Regensburg (DE)

(21) Appl. No.: 12/150,743

(22) Filed: Apr. 30, 2008

(30) Foreign Application Priority Data
Apr. 30, 2007 (DE) 10 2007 020 289.1
Jul. 26, 2007 (DE) 10 2007 034 958.2

(51) Int. Cl. H01S 5/026

(52) U.S. Cl. 372/50.23

(57) ABSTRACT

A beam combiner is specified for a multicolor laser display having an optical light source (1) which has at least two semiconductor lasers (11, 13), in which the beam combiner has a lens (14), and the lens (14) is arranged in a beam path which is formed by beams emitted from the at least two semiconductor lasers (11, 13).

### RELATED APPLICATIONS

This application claims the priority of German patent application nos. 10 2007 020 289.1 filed Apr. 30, 2007 and 10 2007 034 958.2 filed Jul. 26, 2007. The entire content of both of which is hereby incorporated by reference.

### FIELD OF THE INVENTION

The invention relates to a beam combiner for a multicolor laser display, and to a multicolor laser display having a beam combiner.

### BACKGROUND OF THE INVENTION

In a multicolor laser display, laser beams emitted by a laser light source are, for example, projected onto a screen, in order to display a multicolor image. The lasers of the laser light source emit, for example, laser beams in the colors red, green and blue. In order to display the multicolor image with good quality, the projected laser beams should have good beam coincidence on the screen. The laser beams are, for example, combined by a beam combiner and are projected onto the screen, in order to display the multicolor image.

A prismatic beam combiner can be used as the beam combiner. A prismatic beam combiner is known, for example, from the document U.S. Pat. No. 6,154,259 A. The side surfaces of the prisms have different dielectric coatings, the reflection and transmission of which are set such that the different colors are input on different side surfaces of the prismatic beam combiner. For example, red, green and blue beams are input on three different side surfaces. The three beams emerge on a fourth side surface in a combined form from the prismatic beam combiner, in order for example to be projected onto a screen.

Beam combination can also be achieved by beam combiner platelets. In this case, dielectrically coated glass platelets are used for beam combination. At least two beams of different color which arrive at the beam combiner platelet from two directions at an angle of 90° to one another are combined. In this case, by way of example, a beam of one color is reflected, and a beam of the other color is transmitted.

Beam combiners with dichroic mirrors for the combination of beams are known, for example, from the document U.S. Pat. No. 6,426,781 B1.

### SUMMARY OF THE INVENTION

One object of the invention is to provide a beam combiner for a multicolor laser display in which beam coincidence of the emitted beams is achieved in a comparatively simple manner, in particular with as few components as possible. A further object is to provide a multicolor laser display with an improved beam combiner.

These and other objects are attained in accordance with one aspect of the present invention directed to a beam combiner for a multicolor laser display that comprises an optical light source which has at least two semiconductor lasers. The emitted beams from the semiconductor lasers are at different wavelengths, that is to say they have different colors. In particular, the optical light source may have three semiconductor lasers which emit the beams in the colors red, green and blue.

The beam combiner contains a lens which is arranged in the beam path which is formed by the beams emitted from the at least two semiconductor lasers. The beams from the semiconductor lasers are preferably formed to be at least partially coincident by means of the lens.

The beam combiner has an advantageously simple design, with only a small number of components being used, preferably just one single lens. The beam combiner can, therefore, also be adjusted easily. Further advantages are the comparatively low costs for production of the beam combiner, as well as its small physical size.

The at least two semiconductor lasers each have emission points which, in one advantageous embodiment, are at a distance of less than 500 μm from one another and/or from an optical axis of the lens. The expression the “emission point” of the semiconductor laser means the point at which the center point of the emitted laser beam emerges from the semiconductor body of the semiconductor laser. The emission points of the semiconductor lasers are preferably at a distance of less than 100 μm from one another and/or from an optical axis of the lens. A short distance between the respective emission points and the optical axis makes it easier to ensure that the emitted beams can be made coincident by the lens. Beam coincidence is improved by reducing the distance between the emission points. It is possible for the beams to leave the lens with a beam divergence, with the expression a “beam divergence” meaning the angle between the beam and the optical axis of the lens. The beam divergence becomes less the shorter the distance between the emission points and the optical axis, or the longer the focal length of the lens is.

It is also advantageous for the lens to be arranged a short distance from the emission points of the semiconductor lasers. The distance between the emission points of the semiconductor lasers and the lens is preferably 5 mm or less, particularly preferably 3 mm or less.

In a further advantageous embodiment, a prism is arranged in the beam path downstream from the lens. After passing through the prism, the beams are preferably parallel. It is also possible to design or to arrange the prism such that the beams have a predetermined beam divergence after emerging from the prism.

In a further advantageous embodiment, a birefringent plate, in particular composed of birefringent glass, is arranged in the beam path downstream from the lens. The beams emitted from the semiconductor lasers, for example two semiconductor lasers, have polarization directions which differ by 90°. When the beams pass through the plate, the birefringence results in one of the beams being refracted to a greater extent than the other beam, so that the beams are preferably parallel to one another after passing through the plate. It is also possible for the beams to diverge from one another with a predetermined beam divergence after passing through the plate composed of birefringent glass.

In a further advantageous embodiment, a further lens is arranged in the beam path downstream from the lens and acts as a collimator. After passing through the further lens, the beams are preferably parallel or have a predetermined beam divergence.

In a further embodiment, a diffractive element is arranged in the beam path downstream from the lens. The beams are diffracted differently by the diffractive element, depending on the wavelength, so that they are preferably parallel to one another or have a predetermined beam divergence after leaving the diffractive element. The diffractive element may be an element which diffracts on the surface, for example a grating or a surface hologram, or an element which diffracts in the volume, for example a volume hologram.

In the case of beams at different wavelengths, the positions of the focal points of the lens may differ owing to the dispersion of the material of the lens, for example glass or plastic. In one advantageous embodiment, the lens is an achromatic lens, so that the effect of the dispersion is reduced, or even completely eliminated. An achromatic lens contains a combination of at least two glass types in order to reduce the chromatic aberration. The focal points of the lens for the various wavelengths of the plurality of semiconductor lasers in this case advantageously lie on a plane, or at least virtually on a plane.

By way of example, the lens may be a spherical lens or an aspheric lens. The lens preferably has at least one free-form area which advantageously makes it possible to match the optical characteristics of the lens specifically to the arrangement of the semiconductor lasers in the optical light source, in order to achieve good beam coincidence of the emitted laser beams. A lens free-form area which is suitable for the respective optical light source may be intended for a predetermined geometric arrangement of the semiconductor lasers and the lens, and for predetermined wavelengths of the emitted laser beams, by means of simulation calculations.

In a further embodiment, the lens is a diffractive optical element (DOE). The diffractive optical element which acts as a lens is preferably a glass or plastic plate which is provided with diffractive surface structures. The surface structures in this case have dimensions which are generally smaller than the wavelength of the laser radiation which is intended to be focused. Alternatively, the diffractive optical element may also be a volume hologram. A suitable surface structure or a suitable volume hologram of the diffractive optical element may be calculated for the desired imaging characteristics, by means of simulations.

In one preferred refinement, the diffractive optical element has a plurality of optical axes for the various wavelengths of the semiconductor lasers. This refinement makes use of the fact that the diffraction characteristics of the diffractive optical element depend on the wavelength of the semiconductor-laser light to be focused. A suitable surface structure or a suitable volume hologram can be used to ensure that the diffractive optical element has a plurality of optical axes for the various emission wavelengths of the semiconductor lasers. The plurality of optical axes are advantageously arranged offset with respect to one another, to be precise preferably such that the optical axis for one specific wavelength in each case runs collinearly with the emission direction of the semiconductor laser which emits this wavelength.

In one alternative refinement, the optical axes of the diffractive optical element which acts as a lens run at an angle to one another. This results in “squinting” of the laser beams, thus making it possible to further improve the beam coincidence.

In a further advantageous embodiment, the at least two semiconductor lasers are arranged parallel one above the other with mutually facing emission layers. In this embodiment, for example, each of the semiconductor lasers may have a substrate, with the semiconductor lasers being arranged such that the substrates face away from one another. The distance between the emission points of the at least two semiconductor lasers is advantageously short in this embodiment, preferably 20 μm or less, thus in particular making it possible to arrange the emission points of the semiconductor lasers very close to the optical axis of the lens.

In a further advantageous embodiment, the optical light source has three semiconductor lasers which are arranged, to ensure that the emitted beams are in each case coincident, with mutually facing emission layers in a triangle. Each of the semiconductor lasers has, for example, a substrate, with the substrates facing away from one another. The substrates therefore form a triangle, with the emission layers arranged on the substrates pointing toward the inside of the triangle. This makes it possible to ensure that the distances between the emission points of the three semiconductor lasers are advantageously short, and are preferably 100 μm or less. In particular, this makes it possible to arrange the emission points of the semiconductor lasers very close to the optical axis of the lens. The emission points are advantageously at the same distance from one another, and are preferably also at the same distance from the optical axis of the lens.

In one preferred embodiment, the at least two semiconductor lasers are arranged alongside one another on a common substrate. In a further preferred embodiment, the at least two semiconductor lasers are monolithically integrated on a substrate, that is to say they are arranged in a common layer stack.

In a further advantageous embodiment, at least one of the at least two semiconductor lasers is arranged offset with respect to at least one of the semiconductor lasers in a direction which runs parallel to the optical axis of the lens. In this case, for example, the distance between the semiconductor laser that is arranged offset and the lens is shorter than the distance between the other semiconductor laser and the lens. This advantageously makes it possible to reduce or entirely compensate for the effect of dispersion of the lens, as a result of which the lens has different focal lengths for the different-colored laser beams. The offset arrangement of the different-colored lasers allows the focal points of the emitted beams to lie on a plane, in particular on a screen of a laser display.

At least one of the at least two semiconductor lasers in the optical light source may be an edge-emitting semiconductor laser. Furthermore, at least one of the at least two semiconductor lasers may also be a surface-emitting semiconductor laser with a vertical resonator (VCSEL) or a surface-emitting semiconductor laser with an external vertical resonator (VECSEL).

The optical light source may, in particular, at the same time contain at least one edge-emitting and at least one surface-emitting semiconductor laser.

For example, the optical light source may in each case have a red and a blue edge-emitting semiconductor laser, and a green surface-emitting semiconductor laser. A surface-emitting semiconductor laser is preferably used in particular for the color green since green edge-emitting semiconductor lasers are more difficult to produce than blue or red edge-emitting semiconductor lasers.

The beam emitted from a surface-emitting semiconductor laser, in particular VCSEL or VECSEL, generally has a different beam profile than the beam of an edge-emitting semiconductor laser. If the optical light source has at least one edge-emitting semiconductor laser and at the same time at least one surface-emitting semiconductor laser, a spherical lens is advantageously arranged in the beam path of the frequency-doubled semiconductor laser in order to achieve emitted beams with identical beam profiles.

In a further advantageous embodiment, at least one of the at least two semiconductor lasers is a frequency-doubled semiconductor laser. In particular, the frequency-doubled semiconductor laser may be a surface-emitting semiconductor laser, for example a VCSEL or a VECSEL, or a DFB (distributed feedback) laser.

In a further advantageous embodiment, the beam combiner has drive electronics for the semiconductor lasers, which drive electronics are suitable to drive the semiconductor lasers with a time offset to achieve at least partial beam coincidence.

In a multicolor laser display which contains a beam combiner according to the invention, the beams emitted by the semiconductor lasers are, for example, projected via a scanner mirror onto a screen in order to display an image there. The beams are advantageously made coincident by the beam combiner such that the beams entirely or at least partially overlap on arriving at the screen. In this case, the distance between the screen and the scanner mirror may be variable.

### BRIEF DESCRIPTION OF THE DRAWINGS

FIG. 1 shows a schematic illustration of one embodiment of a multicolor laser display with one embodiment of a beam combiner;

FIGS. 2A-2E show examples of beam images on a screen for various embodiments of the beam combiner;

FIGS. 3A and 3B show a schematic illustration of one embodiment of the beam combiner with three semiconductor lasers;

FIGS. 4A and 4B show a schematic illustration of one embodiment of the beam combiner with two semiconductor lasers;

FIG. 5 shows a schematic illustration of one embodiment of the beam combiner with three semiconductor lasers which are arranged in a triangle;

FIG. 6 shows a schematic illustration of one embodiment of the beam combiner with semiconductor lasers arranged one above the other;

FIG. 7 shows a schematic illustration of one embodiment of the beam combiner with a monolithically integrated semiconductor laser;

FIG. 8 shows a schematic illustration of one embodiment of the beam combiner with a semiconductor laser arranged offset;

FIG. 9 shows a schematic illustration of one embodiment of the beam combiner with two edge-emitting laser diodes and a frequency-doubled semiconductor laser;

FIGS. 10A and 10B show a schematic illustration of one embodiment of the beam combiner with a spherical lens arranged above the two edge-emitting laser diodes;

FIG. 11 shows a schematic illustration of one embodiment of the beam combiner with a prism,

FIG. 12 shows a schematic illustration of one embodiment of the beam combiner with a collimator lens;

FIG. 13 shows a schematic illustration of one embodiment of the beam combiner with a diffractive element;

FIG. 14 shows a schematic illustration of one embodiment of the beam combiner with a lens with a free-form area; and

FIG. 15 shows a schematic illustration of one embodiment of the beam combiner with edge-emitting laser diodes arranged one above the other and with a spherical lens;

FIGS. 16A and 16B show a schematic illustration of one embodiment of the beam combiner with a diffractive optical element acting as a lens;

FIGS. 17A and 17B show a schematic illustration of a further embodiment of the beam combiner with a diffractive optical element acting as a lens; and

FIGS. 18A and 18B show a schematic illustration of a further embodiment of the beam combiner with a diffractive optical element acting as a lens.

### DETAILED DESCRIPTION OF THE DRAWINGS

Identical elements or elements having the same effect are provided with the same reference symbols in the figures. The figures should not be regarded as being to scale, and in fact individual elements may have their size exaggerated for illustrative purposes.

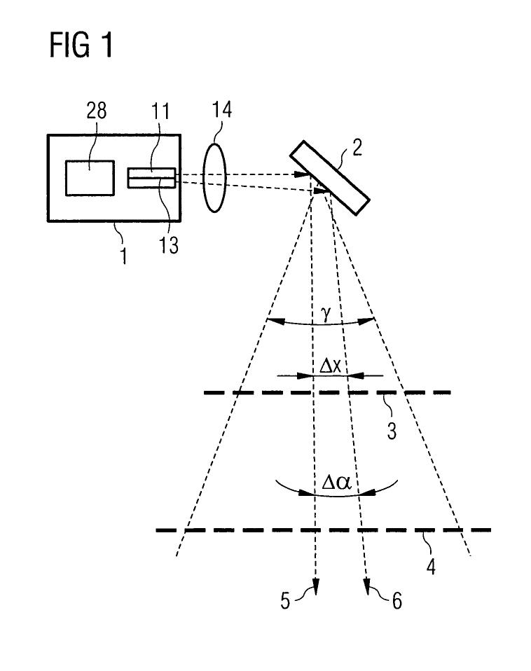

FIG. 1 shows a schematic illustration of a multicolor laser display with a beam combiner. The beam combiner comprises an optical light source 1 which contains two semiconductor lasers 11, 13, and a lens 14 which is arranged in the beam path of the light beams 5, 6 emitted by the semiconductor lasers 11, 13. The laser display also contains a scanner mirror 2 for deflection of the laser beams 5, 6 emitted by the semiconductor lasers 11, 13 onto a screen 3. The further screen 4 which is illustrated, and is further away from the scanner mirror 2, is intended to indicate that the distance between the screen 3 and the scanner mirror 2 is not fixed, but in fact that the screen 3, 4 can be arranged at different distances from the scanner mirror 2.

In this embodiment, the optical light source 1 has two semiconductor lasers 11, 13. For example, one semiconductor laser 11 emits red light at a wavelength of, for example, 660 nm. The other semiconductor laser 13, for example, emits blue light at a wavelength of, for example, 440 nm.

The red laser beam 5 and the blue laser beam 6 are emitted by the semiconductor lasers 11, 13 in the optical light source 1 of the beam combiner, and arrive at the scanner mirror 2. The scanner mirror 2 projects the red beam 5 and the blue beam 6 onto the screen 3, 4. On arriving at the screen 3, 4, the beams 5, 6 have a beam offset Δx on the screen 3, 4. The red beam 5 and the blue beam 6 have a beam divergence Δα with respect to one another on arriving at the screen 3, 4.

The beams 5, 6 are projected onto the screen 3, 4 by the scanner mirror 2 with a scan angle γ, such that a multicolor image is written on the screen 3, 4 by means of a so-called flying-spot method. The beams 5, 6 are deflected on the screen 3, 4 both in the horizontal direction (x-direction) and in a vertical direction (y-direction, not illustrated) running at right angle to the plane of the drawing.

The beams 5, 6 are advantageously at least partially coincident, so that they at least partially overlap on the screen 3, 4. The beam offset Δx should preferably be +/−0.1 mm or less. The beam divergence Δα with which the beams arrive at the screen should preferably be less than +/−0.02°. The smaller the beam divergence Δα and the shorter the distance between the emission points of the semiconductor lasers, the further the screen 3, 4 may be arranged away from the scanner mirror 2 without the beam offset Δx becoming sufficiently large that the beams are no longer coincident. The lens 14 contained in the beam combiner advantageously reduces the beam divergence Δα of the light beams 5, 6 even before they arrive at the scanner mirror 2.

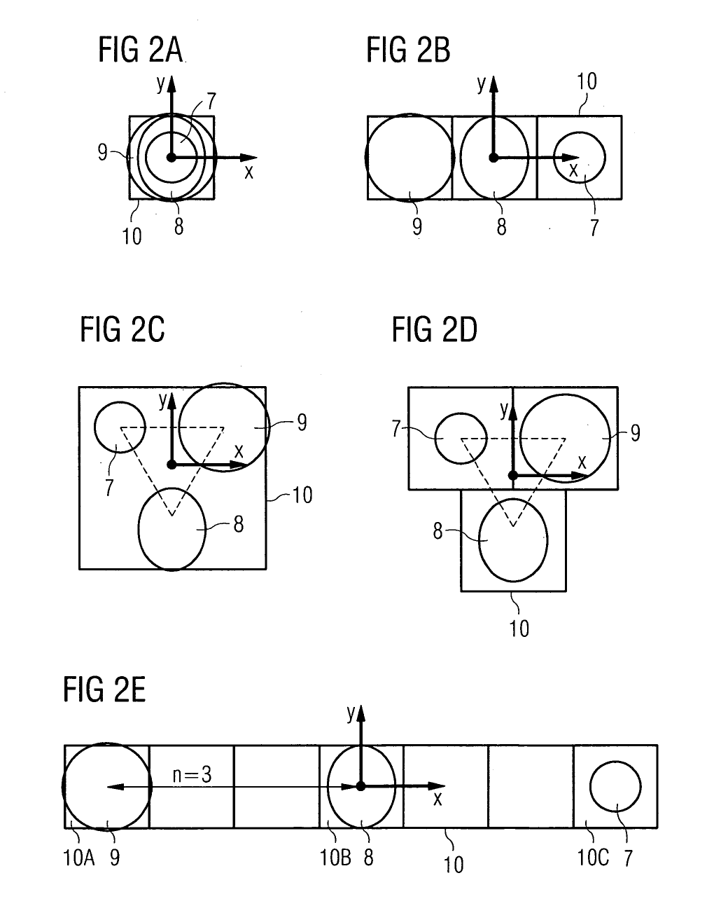

The beam combiner advantageously contains drive electronics 28 for the semiconductor lasers 11, 13, which drive electronics 28 are, for example, integrated in the optical light source 1. The operation of the drive electronics 28 will be explained in more detail in the following text with reference to FIGS. 2A-2E.

FIGS. 2A-2E show, schematically, a plurality of examples of possible beam images on a screen, which can be achieved by the beam combiner. The optical light source, which is not illustrated, in this embodiment has three semiconductor lasers which emit beams in the colors red, green and blue. FIGS. 2A to 2E show, by way of example, the positions of the beam cross sections on the screen of a laser display which has a multiplicity of pixels 10.

FIG. 2A shows a beam cross section 7 of the blue laser, a beam cross section 8 of the green laser, and a beam cross section 9 of the red laser. The situation illustrated here represents the ideal case, in which the beam cross sections 7, 8, 9 of the beams emitted by the semiconductor lasers arrive at a single pixel 10 on the screen without any beam discrepancies.

If the emitted beams have a beam divergence Δα with respect to one another on arrival at the screen of the laser display, this makes it more difficult to achieve ideal beam coincidence.

FIG. 2B shows an example in which the blue beam cross section 7, the red beam cross section 9 and the green beam cross section 8 each arrive at adjacent pixels 10 in one line. The green beam 8 therefore arrives at the screen with an offset of one pixel in the x-direction with respect to the red beam 9. The blue beam 7 arrives at the screen with an offset of 2 pixels in the x-direction from the red beam.

A beam offset such as this can be compensated for by means of drive electronics for the semiconductor lasers, without any further optical elements. For this purpose, the drive electronics drive the semiconductor lasers with a time offset such that, for example, at one specific position of the scanner mirror, the red laser is operated with the color information of one specific image point, the green laser is operated with the color information of the image point offset by one pixel, and the blue laser is operated with the color information of the image point offset by two pixels. In this way, the drive electronics ensure that the color information for the red, green and blue of one image point are imaged in the same pixel on the screen. This, therefore, results in the drive electronics producing the state shown in FIG. 2A when writing the image. However, in this embodiment, two pixels 10 are in each case lost at the edges of the screen since all three colors cannot arrive there and they therefore cannot be used for image production.

FIG. 2C shows a situation in which the beams are projected onto the screen such that they arrive at the screen somewhat offset with respect to one another both in the x-direction and in the y-direction. The diameter of the beam cross sections 7, 8, 9 is, for example, between 250 μm and 450 μm and, for example, the distances between the beam center points are 300 to 800 μm. In FIG. 2C, the positions of the three beam cross sections 7, 8, 9 are comparatively close to one another on the screen, so that they can jointly form one pixel 10 of the display. The pixel 10 therefore contains all three colors. However, the pixel size of the pixel 10 is larger than the ideal beam coincidence as illustrated in FIG. 2A, despite the laser beams having the same beam diameter, so that the image quality is reduced.

FIG. 2D shows a better solution for the situation illustrated in FIG. 2C, in which suitable drive electronics are used to avoid a reduction in the resolution resulting from a beam offset between the laser beams. The three beams which arrive at the screen with an offset and each have a beam cross section 7, 8, 9 each produce different pixels 10 of the image. The drive electronics drive the semiconductor lasers with suitable time offsets in a similar manner to the example illustrated in FIG. 2B to ensure that the color information for the red, green and blue of each image point is imaged in the same pixel 10 on the screen.

In the situation in which the laser beams arrive at the screen with a beam offset which is so great that they cannot be used to produce adjacent pixels 10, it is possible for the distance between the beams to also be a plurality of pixels 10 of the image. FIG. 2E shows a situation such as this. The red beam arrives with the beam cross section 9 at a first pixel 10A, and a green beam arrives at a further pixel 10B with the beam cross section 8, with this further pixel 10B being at a pixel separation n from the first pixel 10A. The pixel separation n corresponds to the beam offset Δx on the screen. In this embodiment, the pixel separation is n=3 pixels. Furthermore, a blue beam arrives with the beam cross section 7 with a further pixel separation of n=3 pixels on the extreme right-hand side pixel 10C as shown in FIG. 2E.

In this embodiment, as already described above in conjunction with FIGS. 2B and 2D, the beam coincidence is achieved by means of the drive electronics, although there are more pixels which cannot be used for image production on each side of the screen, however, as the pixel separation n between the offset beams increases. However, this pixel separation n can be reduced by using the lens 14 of the beam combiner to minimize the beam divergence Δα, so that the beam offset Δx between the beams on the screen is small and the pixel separation n is only a few pixels.

It is also advantageous for a beam offset, as in the case of the examples in FIG. 2B and FIG. 2E, to be only within one line of pixels 10, that is to say in the direction of the x-axis, since the image is written in this direction. In this case, the drive electronics complexity is less than if a beam offset in the columns of pixels 10, that is to say in the direction of the y-axis, also have to be corrected by the drive electronics at the same time, as is the case in the example shown in FIG. 2D.

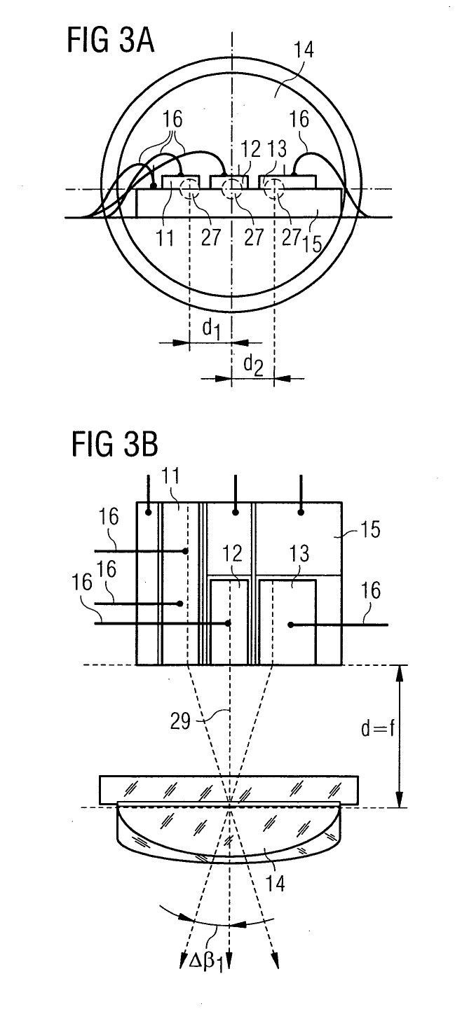

FIGS. 3A and 3B show an embodiment of the beam combiner with a lens 14 and a red semiconductor laser 11, a green semiconductor laser 12 and a blue semiconductor laser 13, which are arranged on a heat sink 15. FIG. 3A shows a view through the lens 14 of the semiconductor lasers 11, 12, 13 of the optical light source, and FIG. 3B shows a plan view of the beam combiner.

FIG. 3A shows the three semiconductor lasers 11, 12, 13 arranged alongside one another on the heat sink 15. In this embodiment, the three semiconductor lasers 11, 12, 13 are edge-emitting laser diodes and are soldered to the heat sink 15 alongside one another. The semiconductor lasers 11, 12, 13 are arranged on the heat sink 15 such that their p-side contact faces the heat sink. The lens 14 is produced, for example, from glass or plastic.

The semiconductor lasers 11, 12, 13 each have a wire contact 16 and can be electrically driven individually. Each of the three semiconductor lasers 11, 12, 13 has an emission point 27. The green semiconductor laser 12 is arranged on an optical axis of the lens 14. The distance d1 between the emission point 27 of the red semiconductor laser 11 and the optical axis of the lens 14, as well as the distance d2 between the emission point 27 of the blue semiconductor laser 13 and the optical axis 29 of the lens 14, should be as short as possible in order to ensure good coincidence of the beams which are emitted by the semiconductor lasers 11, 12, 13.

The distances between the emission points 27 of the semiconductor lasers 11, 12, 13 and the optical axis 29 of the lens 14 are preferably less than 500 μm, particularly preferably less than 100 μm. This means that the semiconductor lasers 11, 12, 13 are at very short distances from one another on the heat sink 15.

FIG. 3B shows a plan view of the beam combiner shown in FIG. 3A. The lens 14 is arranged at a distance d, which is preferably equal to the focal length f of the lens 14, from the emission points 27 of the semiconductor lasers 11, 12, 13. The distance between the lens d and the emission points 27 of the semiconductor lasers 11, 12, 13 is preferably 5 mm or less, particularly preferably 3 mm or less, for example 2 mm. The emitted beams pass through the lens 14. FIG. 3B shows those semiconductor-laser beams which pass through the center point of the lens 14. For example, a beam from the blue semiconductor laser 13 which is emitted in the direction of the lens center point passes through the lens 14 with a beam divergence of Δβ1=arctan (d1/f) with respect to the optical axis 29. The beam divergence Δβ1 decreases the shorter the distance d1 between the emission point 27 of the semiconductor laser 11 and the optical axis of the lens 14, and the longer the focal length f of the lens 14.

The beam divergence Δβ1 can lead to the beam from the blue semiconductor laser 13 arriving at the screen offset by n pixels with respect to the beam from the green semiconductor laser 12, the emission point of which is arranged on the optical axis 29 of the lens. If the display scan angle is γ and the number of pixels per line is N, then the pixel separation n for the offset at which the beams arrive at the screen is:

n=N(Δβ1/γ)=N[arctan(d1/f)/γ].

In a mathematical example, the distance d1 between the emission point 27 of the red semiconductor laser and the optical axis of the lens is, for example, 100 μm. The focal length f of the lens is 2 mm. The scan angle γ is 44°, and the total number N of pixels in one line on the screen is 640. The pixel separation n in one line, that is to say in the x-direction on the screen, is then 42 pixels.

Since the beams emitted by the semiconductor lasers 11, 12, 13 are at different wavelengths, it is possible for the focus points of the beams not to lie on one plane, because of dispersion. The influence of dispersion can be reduced or cancelled out entirely by using an achromatic lens 14 or a lens composed of a special glass with little dispersion.

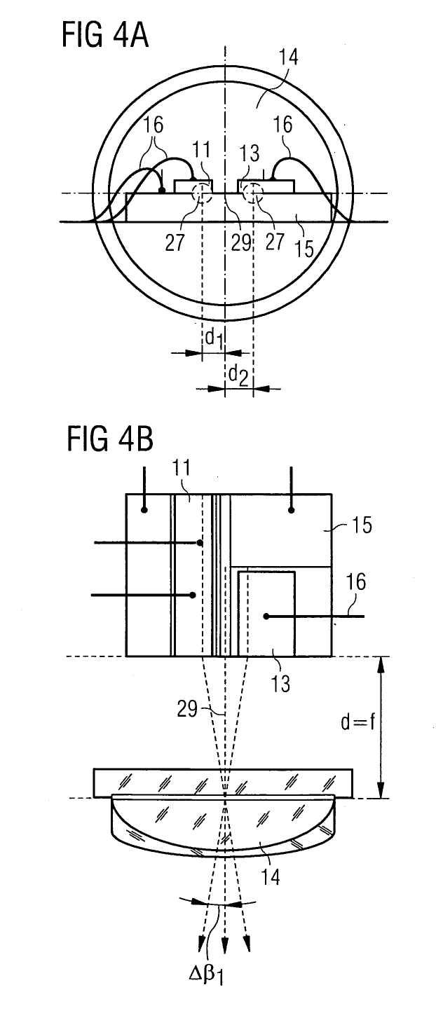

FIGS. 4A and 4B show a further embodiment of the beam combiner with two semiconductor lasers 11, 13. FIG. 4A shows a view through the lens 14 of the semiconductor lasers 11, 13 of the optical light source. FIG. 4B shows a plan view of the beam combiner.

FIG. 4A shows the lens 14, the red semiconductor laser 11 and the blue semiconductor laser 13, which are arranged alongside one another on the heat sink 15. As in the embodiment of FIGS. 3A and 3B, the semiconductor lasers 11, 13 are edge-emitting laser diodes and are electrically driven individually via wire contacts 16. The semiconductor lasers 11, 13 are preferably arranged on the heat sink 15 such that their p-side contact faces the heat sink.

The distance d1 between the emission point 27 of the red semiconductor laser 11 and the optical axis 29 of the lens 14, and the distance d2 between the emission point 27 of the blue semiconductor laser 13 and the optical axis 29 of the lens 14 should in each case be as short as possible, so that the beams arrive at the lens 14 with a small beam divergence with respect to the optical axis 29. As illustrated in FIG. 4B, for example, a beam emitted in the direction of the lens center point from the blue semiconductor laser 13 has a beam divergence Δβ1 after passing through the lens. The beam divergence Δβ1 is less than in the embodiment in FIG. 3B, since the distance d1 between the emission point 27 of the semiconductor laser 11 and the optical axis of the lens 14 is shorter. The beam offset on the screen can be reduced in this way, thus resulting in a better image quality.

FIG. 5 shows a further embodiment of the beam combiner 1 with three semiconductor lasers 11, 12, 13 which are arranged in a triangle. The figure shows a view through the lens 14 to an arrangement with three semiconductor lasers 11, 12, 13, with the semiconductor lasers 11, 12, 13 each being arranged on the substrate 26.

The respective emission layers of the semiconductor layers 11, 12, 13 face one another. The semiconductor lasers 11, 12, 13 are advantageously arranged such that the p-contact faces on the side of the semiconductor lasers 11, 12, 13 which faces away from the substrate 26 are opposite one another. This makes it possible to achieve shorter distances between the emission points 27 and the optical axis of the lens 14 than in the case of an arrangement in which the substrates of the semiconductor lasers are opposite.

The emission points 27 of the semiconductor lasers 11, 12, 13 are shown as circles and, in this embodiment, are arranged very close to the optical axis of the lens 14. The optical axis of the lens 14 passes through the center point of the lens, which is located at the intersection of the dashed lines. The distance between the emission points is preferably 100 μm or less, particularly preferably 50 μm or less, thus making it possible to achieve good beam coincidence and therefore a small beam offset Δx on a screen. The respective emission points 27 are preferably at equal distances from the optical axis of the lens 14.

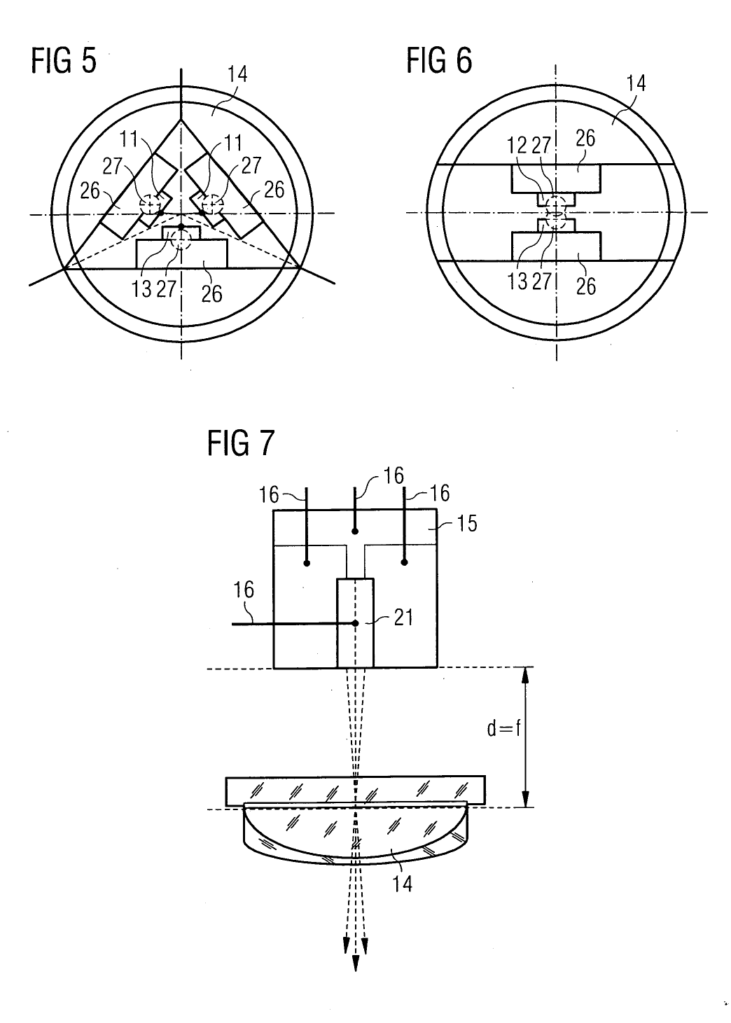

FIG. 6 shows a further embodiment of the beam combiner, in which the semiconductor lasers are arranged one above the other. The figure shows a view through the lens 14 of two semiconductor lasers 11, 13 which are arranged parallel, one above the other. The semiconductor lasers 11, 13 are each located on a substrate 26, with the substrates 26 facing away from one another. In this embodiment, the emission layers of the respective semiconductor lasers 11, 13 face one another. For example, the semiconductor laser 11 is arranged inverted above the semiconductor laser 13. An arrangement such as this results in the distance between the emission points 27 of the respective semiconductor lasers 11, 13 and the optical axis of the lens, which is located at the point formed by the intersection of the dashed lines, being very short. The distance between the emission points 27 of the semiconductor lasers 11, 13 is advantageously only 20 μm or less, particularly preferably only 10 μm or less. This results in good beam coincidence.

In this embodiment, the semiconductor lasers 11, 13 are preferably arranged on the respective substrate 26 such that the p-side contacts of the semiconductor lasers 11, 13 are each arranged on the surface opposite the substrate 26.

The mutually opposite semiconductor lasers are in this case either arranged separated from one another by a thin air gap, as illustrated in FIG. 6, or are connected to one another on their p-contact side. For example, the p-contact sides of the semiconductor lasers can be soldered to one another so that they are separated from one another by a solder layer with a preferred thickness of only 1 μm to 8 μm. Soldering the semiconductor lasers 11, 13 to one another also has the advantage that this results in them being thermally linked. For example, the blue semiconductor laser 13 may have a substrate 26 composed of GaN, which is distinguished by good thermal conductivity. If the semiconductor lasers 11, 13 are thermally linked, the heat of the other semiconductor laser 11 which, for example, is a red semiconductor laser, can also advantageously at least partially be dissipated via the substrate of the blue semiconductor laser 13.

FIG. 7 shows a plan view of a further embodiment of the beam combiner, in which the light source has a monolithically integrated multicolor semiconductor laser 21. The monolithically integrated semiconductor laser 21 contains a plurality of emission layers, which are arranged on a common substrate. In particular, the plurality of emission layers may be arranged one above the other in an epitaxially produced layer system of the semiconductor laser 21. The monolithically integrated semiconductor laser 21 preferably contains three emission layers for the colors red, green and blue. The plurality of emission layers can be driven individually via the contacts 16.

The emission points of the plurality of emission layers in the monolithically integrated semiconductor laser 21 are advantageously separated from one another by only a few μm. It is, therefore, possible for all the emission points to be arranged virtually on the optical axis of the lens 14. Also after passing through the lens 14, the emitted beams therefore have a very small beam divergence. Furthermore, the monolithically integrated semiconductor laser 21 has the advantage that, in contrast to separately manufactured semiconductor lasers, this avoids position errors during assembly.

The monolithically integrated semiconductor laser 21 is preferably arranged on a heat sink 15, in order to dissipate the heat produced during operation.

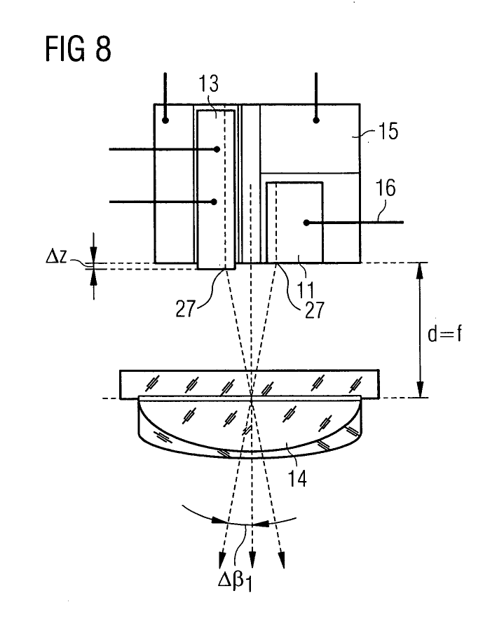

FIG. 8 shows a further embodiment of the beam combiner with two semiconductor lasers 11, 13, which are arranged with their emission directions offset with respect to one another.

By way of example, the optical light source has a red semiconductor laser 11 and a blue semiconductor laser 13. In this embodiment, the semiconductor lasers 11, 13 are edge-emitting laser diodes. The emission point 27 of the blue semiconductor laser 13 is offset by a distance Δz along the optical axis of the lens 14 with respect to the emission point 27 of the red semiconductor laser 11.

The offset arrangement of the semiconductor lasers 11, 13 with the separation Δz compensates for the color error of the lens (chromatic aberration) caused by the dispersion of the lens material, as a result of which the focal points for light at different wavelengths, for example for red light and blue light, do not coincide. For example, if the focal length of the lens is shorter for blue light than for red light because of the dispersion, the blue laser 13 is arranged closer to the lens 14 than the red laser 11.

The use of the offset arrangement of the semiconductor lasers 11, 13 to compensate for the color error of the lens 14 has the advantage that the emitted beams have a smaller beam divergence Δβ1 with respect to the optical axis after passing through the lens 14 than in an arrangement in which the semiconductor lasers are not offset.

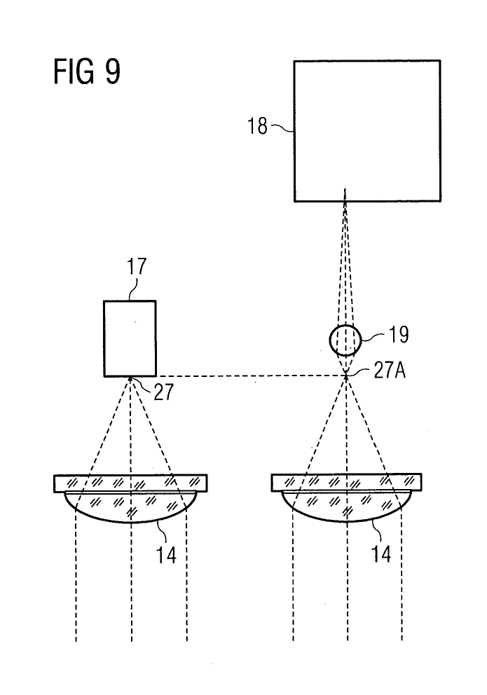

FIG. 9 shows a further embodiment of the beam combiner. The optical light source contains an edge-emitting laser diode 17 which emits red light and blue light. The edge-emitting laser diode 17 may, in particular, have two monolithically integrated emission layers for red light and blue light.

Furthermore, the optical light source contains a frequency-doubled semiconductor laser 18 which emits green light. The frequency-doubled semiconductor laser 18 may, in particular, be a vertical external cavity surface emitting laser (VECSEL), which can be electrically or optically pumped, or a distributed feedback laser. The frequency doubling of the semiconductor laser 18 is achieved for example by means of a non-linear optical crystal. For example, the semiconductor laser 18 may have a fundamental wavelength of 1064 μm, with green light being produced at a wavelength of 532 nm by means of frequency doubling.

The beam profile of the green frequency-doubled semiconductor laser 18 differs from the beam profile of the edge-emitting semiconductor laser 17. This is because frequency-doubled surface-emitting lasers typically have less beam divergence and a wider beam diameter than edge-emitting semiconductor lasers.

The different beam profiles of the semiconductor lasers 17, 18 make it harder to achieve beam coincidence by means of a beam combiner. It is, therefore, advantageous to match the beam profiles of the semiconductor lasers 17, 18 to one another before they pass through the lens 14 of the beam combiner. A spherical lens 19 is preferably arranged in the beam path of the green semiconductor laser 18 in order to match the beam profile of the green semiconductor laser 18 to the beam profile of the edge-emitting semiconductor laser 17. In this embodiment, the spherical lens 19 has a small diameter, in particular of 300 μm or less. The use of this spherical lens 19 with an extremely short focal length makes it possible to match the beam profile of the green beam to that of the red and blue beams from the edge-emitting semiconductor laser 17. The focus 27A of the spherical lens 19 represents a quasi-emission point, from which a beam originates which has a similar beam profile to the beam, originating from an emission point 27, of the edge-emitting semiconductor laser 17.

The red, green and blue beams, therefore, arrive at the lenses 14 of the beam combiner with at least approximately the same beam profile. Instead of the two lenses 14 illustrated for the beams in FIG. 9, it is, in particular, also possible to use a common lens for the red, blue and green beams from the semiconductor lasers 17, 18, thus advantageously simplifying the optical design of the beam combiner.

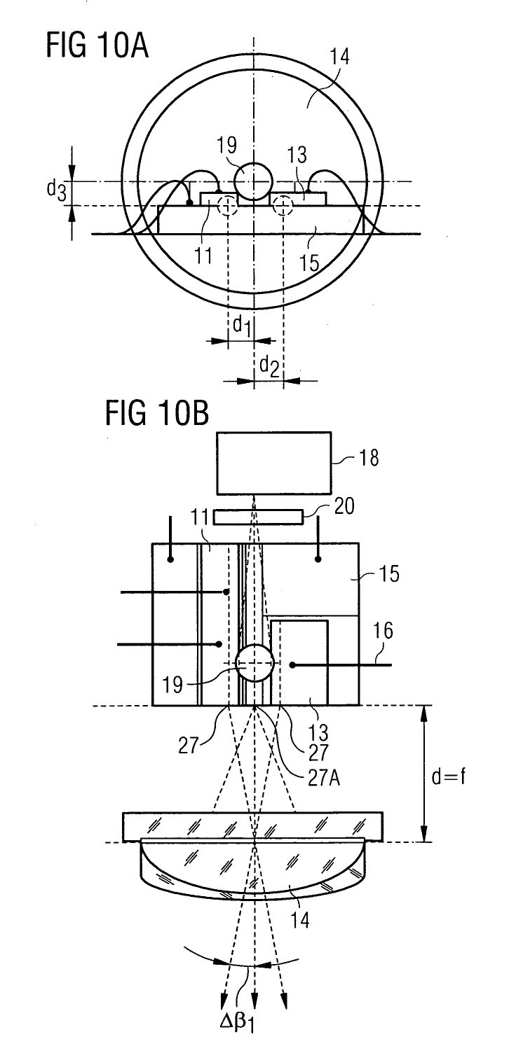

FIGS. 10A and 10B show a further embodiment of the beam combiner 1 with an optical light source formed by three semiconductor lasers 11, 13, 18. FIG. 10A shows a view through the lens 14 of the optical light source, and FIG. 10B shows a plan view of the beam combiner.

The optical light source contains a red semiconductor laser 11 and a blue semiconductor laser 13, which are both edge-emitting semiconductor lasers. Furthermore, the optical light source contains the frequency-doubled semiconductor laser 18 in order to emit the green beam. As in the case of the embodiment described in conjunction with FIG. 9, the frequency-doubled semiconductor laser 18 may, in particular, be a VECSEL.

A spherical lens 19 is provided in order to match the beam profile of the green semiconductor laser 18 to the beam profiles of the red semiconductor laser 11 and of the blue semiconductor laser 13, as in the case of the already described exemplary embodiment. The spherical lens 19 is arranged above the red semiconductor laser 11 and the blue semiconductor laser 13. The emission points 27 of the red semiconductor laser 11 and of the blue semiconductor laser 13 are at distances d1, d2 from the optical axis of the lens 14. The arrangement of the spherical lens 19 above the red and blue semiconductor lasers 11, 13 allows them to be arranged at an advantageously short distance d3 from the optical axis so that the distances d1, d2, d3 from the optical axis are as short as possible.

Alternatively, the spherical lens 19 can also be fitted alongside the red and blue semiconductor lasers 11, 13. This has the advantage that it results in the beams being arranged linearly, as shown in FIG. 2E.

A corrector plate 20, which is designed to be planar or wedge-shaped and can be tilted, is arranged in front of the frequency-doubled semiconductor laser 18. The corrector plate allows the beam from the green semiconductor laser 18 to be deflected such that the focus of the spherical lens 19 for the green beam is at the same height as the emission points 27 of the red and blue semiconductor lasers 11, 13.

It may also be advantageous for the emission points 27 of the red and blue semiconductor lasers 11, 13 and the focus 27A of the spherical lens 19 not to be arranged on one plane. If the emission points 27 of the semiconductor lasers 11, 13 or the focus 27A of the spherical lens 19 is or are arranged offset from one another in the direction of the optical axis of the lens 14, it is possible, for example, to compensate for the dispersion of the lens 14, as in the case of the embodiment shown in FIG. 8.

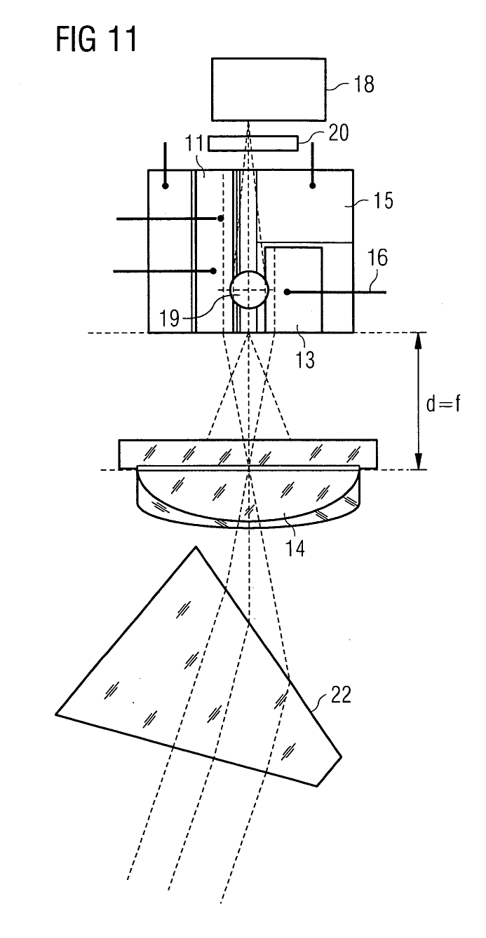

FIG. 11 shows a modification of the beam combiner from FIGS. 10A and 10B, in the form of a further embodiment, in which a prism 22 is arranged in the beam path downstream from the lens 14. The prism 22 reduces the beam divergence of the beams from the semiconductor lasers 11, 13, 18 after passing through the lens 14, with the beams preferably having a beam divergence of virtually equal to zero downstream from the prism 22.

Since the beams diverge from one another downstream from the lens 14 with a beam divergence Δβ1, it is advantageous to reduce the beam divergence as close as possible to the lens 14 in order to achieve as little beam offset as possible. The closer the prism 22 is arranged to the lens 14, the less is the beam offset of the beams on the screen.

The method of operation of the prism 22 is based on the fact that each of the emitted laser beams is at a different wavelength. For example, the blue semiconductor laser 13 is at a wavelength of 440 nm, the green semiconductor laser 18 is at a wavelength of 530 nm, and the red semiconductor laser 11 is at a wavelength of 640 nm. A prism 22 which is placed in the beam path downstream from the lens 14 refracts the beams of the three colors differently because of the dispersion. Suitable choice of the optical glass and of the alignment of the prism 22 with respect to the lens 14 results in the emitted beams being parallel downstream from the prism 22.

In particular, the pixel separation n between the beams on the screen can be reduced by means of the prism 22. For example, the pixel separation can be reduced from forty-four pixels without using the prism 22 to three pixels when using the prism 22.

If the beam offset on the screen is greater than the beam radius of each beam, it is advantageous for the beams not to be aligned parallel but to diverge from one another with a beam divergence of Δβ=γ/N, where γ is the scan angle and N is the number of pixels per line in the laser display. Δβ=γ/N is the angle range which a single pixel occupies. This means that the beams are at the same distance from one another even if the distances between the screen and the source differ. For example, for a scan angle of 44° and a total number N of 640 pixels per line, Δβ=44°/640=0.07°.

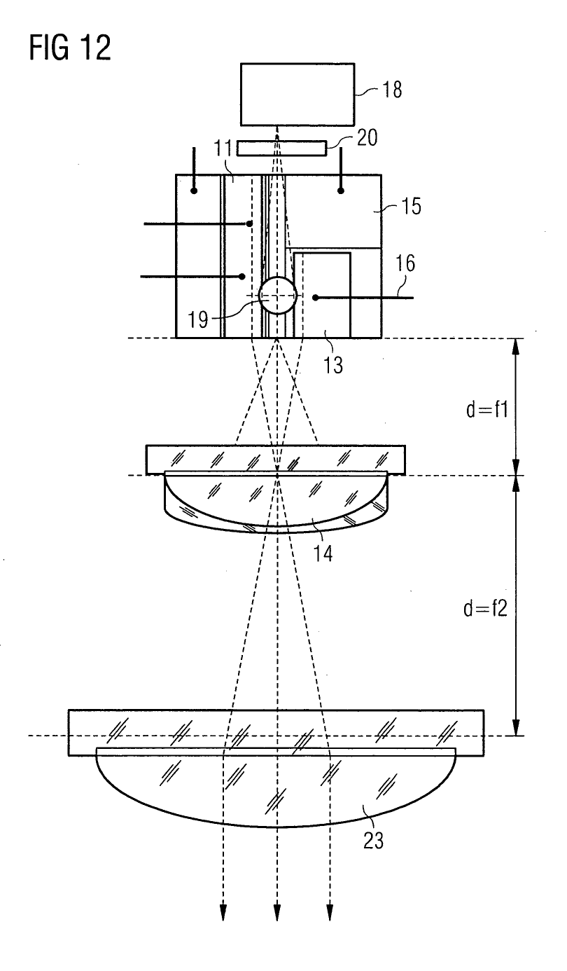

FIG. 12 shows a modification of the beam combiner from FIGS. 10A and 10B in the form of a further embodiment, containing a collimator lens 23 in addition to the lens 14.

In order to reduce the beam divergence, the lens 14 is followed by the collimator lens 23 in the beam path. The distance d between the lens 14 and the collimator lens 23 in this embodiment is preferably equal to the focal length f2 of the collimator lens 23. An arrangement such as this results in the beams preferably being refracted such that they are parallel to one another after passing through the collimator lens 23 or, alternatively as described in conjunction with FIG. 11, having a predetermined beam divergence of Δβ=γ/N.

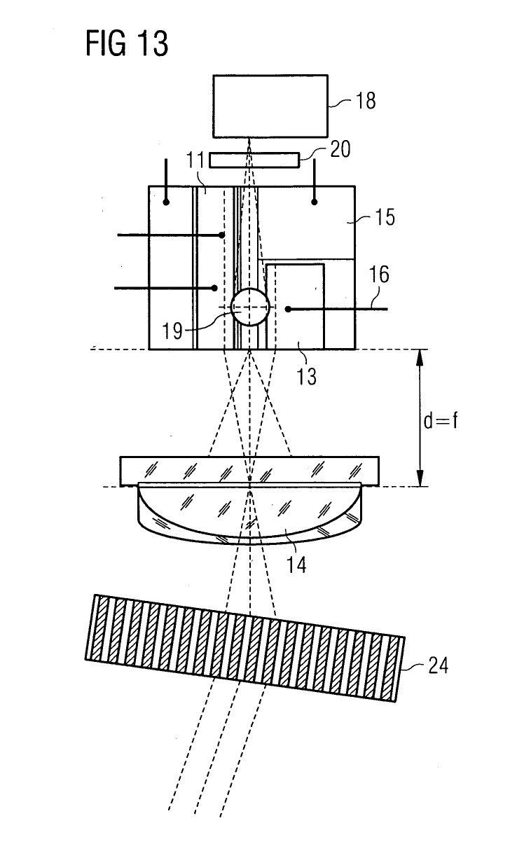

FIG. 13 shows a modification of the beam combiner from FIGS. 10A and 10B in the form of a further embodiment in which the lens 14 is followed by a diffractive optical element 24 in the beam path.

The diffractive optical element 24 diffracts the beams from the red, green and blue semiconductor lasers 11, 18, 13 as a function of their wavelength so that, after passing through the diffractive optical element 24, they are parallel to one another or, for example, diverge from one another with a predetermined beam divergence Δβ=γ/N.

The diffractive optical element 24 may be an element which diffracts on the surface, for example a grating or surface hologram, or an element which diffracts in the volume, for example a volume hologram. Instead of a diffractive optical element 24 it is also alternatively possible to use a plate composed of birefringent material, in particular a birefringent glass, in the beam path downstream from the lens 14, in order to align the beams such that they are parallel or to set a predetermined beam divergence.

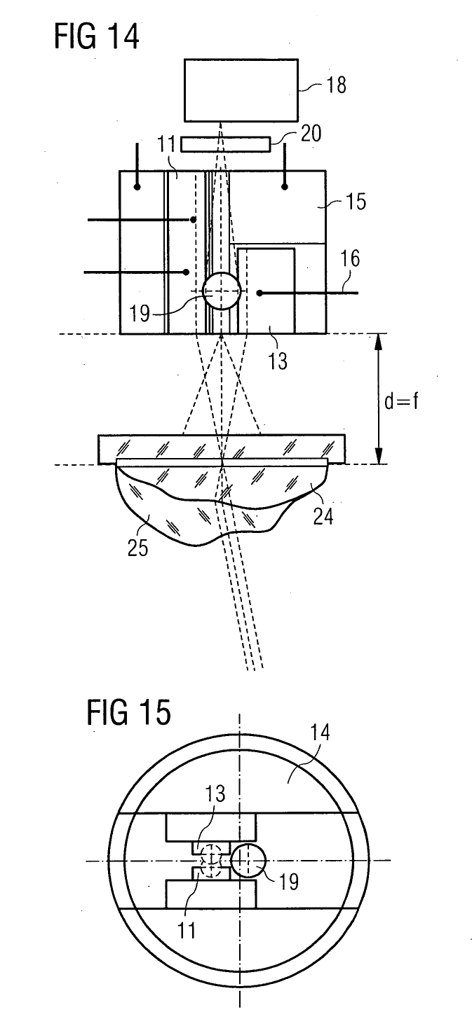

FIG. 14 shows a modification of the beam combiner from FIGS. 10A and 10B in the form of a further embodiment, in which the lens 14 has a free-form area 25. The free-form area is preferably designed such that the beams from the semiconductor lasers 11, 13, 18 are parallel to one another after passing through the lens 14. A suitable free-form area 25 can be defined as a function of the arrangement of the semiconductor lasers 11, 13, 18, for example by means of simulation calculations. The lens 14 may also be an achromatic lens, preferably with two free-form areas.

FIG. 15 shows a further embodiment of the beam combiner, showing a view through the lens 14. The optical light source of the beam combiner has two semiconductor lasers 11, 13 which are arranged one above the other, in the form of two edge-emitting laser diodes, and a frequency-doubled semiconductor laser (not illustrated). A spherical lens 19 is arranged alongside the semiconductor lasers 11, 13, and is arranged in the beam of the frequency-doubled semiconductor laser. The distances between the emission points of the edge-emitting lasers, which are shown as circles, and the spherical lens 19 from the optical axis of the lens 14, which passes through the center point of the lens 14, are very short, preferably less than 100 μm. This results in a small beam divergence Δβ, and therefore in good beam coincidence, so that the beam offset Δx on a screen is advantageously small.

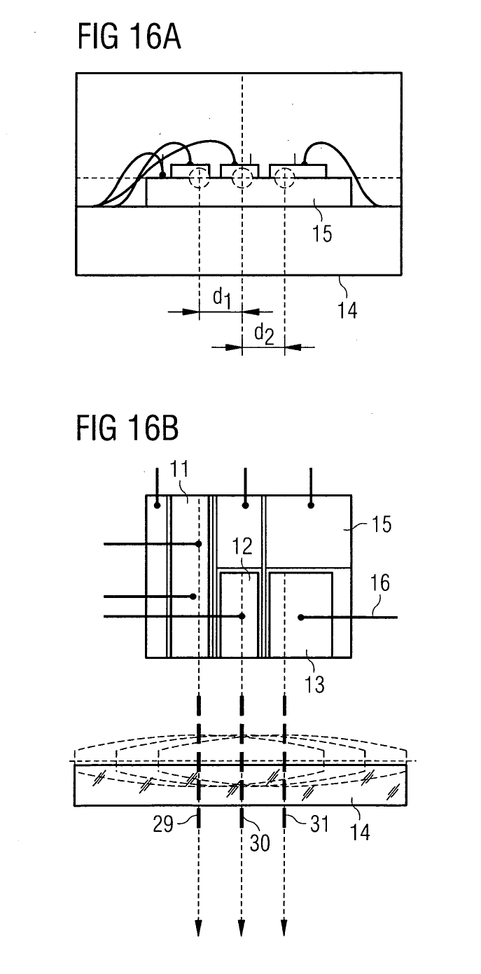

FIGS. 16A and 16B show a further embodiment of the beam combiner, in which the lens 14 is a diffractive optical element. FIG. 16A shows a view through the diffractive optical element, which acts as a lens, of the optical light source, while FIG. 16B shows a plan view of the beam combiner. The optical light source comprises three semiconductor lasers 11, 12, 13, which, in particular, are edge-emitting semiconductor lasers. The diffractive optical element 14 is preferably a glass or plastic plate, which is provided with diffractive surface structures. In this case, the surface structures have dimensions which are generally smaller than the wavelengths of the semiconductor lasers 11, 12, 13. Alternatively, the diffractive optical element 14 may also be a volume hologram. The diffraction structures which are formed in or on the diffractive optical element act as a virtual lens for the laser beams emitted by the semiconductor lasers 11, 12, 13. A suitable surface structure or a suitable volume hologram for the diffractive optical element may be calculated for the desired imaging characteristics of the virtual lens 14 by means of simulations.

The diffractive optical element 14 preferably has a plurality of optical axes 29, 30, 31 for the various wavelengths of the semiconductor lasers 11, 12, 13. This refinement makes use of the fact that the diffractive characteristics of the diffractive optical element 14 are dependent on the wavelength of the semiconductor-laser light to be focused. It is possible to use a suitable surface structure or a suitable volume hologram to ensure that the diffractive optical element 14 has a plurality of optical axes 29, 30, 31 for the various emission wavelengths of the semiconductor lasers 11, 12, 13.

The plurality of optical axes 29, 30, 31 are advantageously arranged offset with respect to one another, to be precise preferably such that the optical axis for the wavelength of one respective semiconductor laser of the optical light source runs collinearly with respect to the emission direction of the respective semiconductor laser. For example, the diffractive optical element 14 has an optical axis 29 for the radiation from the red semiconductor laser 11, with the optical axis 29 running collinearly with respect to the emission direction of the red semiconductor laser 11. Furthermore, the diffractive optical element 14 has an optical axis 30 for the wavelength of the green semiconductor laser 12, which runs collinearly with respect to the emission direction of the green semiconductor laser 12, and is offset by a distance d1 from the optical axis 29 for the wavelength of the red semiconductor laser 11. Furthermore, the diffractive optical element 14 has an optical axis 31 for the wavelength of the blue semiconductor laser 13, which runs collinearly with respect to the emission direction of the blue semiconductor laser 13 and is offset by a distance d2 from the optical axis 30 for the wavelength of the green semiconductor laser 12. The effect of the diffractive optical element 14 therefore corresponds to the effect of three different virtual lenses, which are indicated by the dashed lines in FIG. 16B.

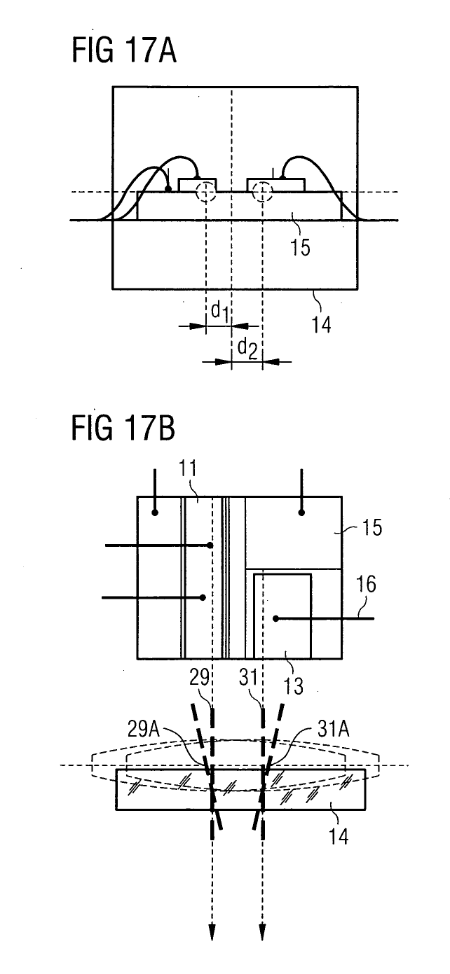

The embodiment of the beam combiner illustrated in FIGS. 17A and 17B corresponds essentially to the embodiment illustrated in FIGS. 16A and 16B, but with the optical light source containing only two semiconductor lasers 11, 13 instead of three semiconductor lasers, specifically a red semiconductor laser 11 and a blue semiconductor laser 13. A diffractive optical element 14 acts as a lens and has an optical axis 29 for the wavelength of the red semiconductor laser 11 which, for example, runs collinearly with respect to the emission direction of the red semiconductor laser 11. Furthermore, the diffractive optical element has a further optical axis 31 for the wavelength of the blue semiconductor laser 13 which, for example, runs collinearly with respect to the emission direction of the blue semiconductor laser 11.

In one alternative preferred refinement, the diffractive optical element 14 has the optical axes 29A, 31A indicated by dashed lines instead of the optical axes 29, 31 which are arranged collinearly with respect to the respective emission directions of the semiconductor lasers 11, 13, which optical axes 29A, 31A run at an angle to one another and to the respective emission directions of the semiconductor lasers 11, 13. This means that the laser beams from the semiconductor lasers 11, 13 run at an angle to one another after passing through the diffractive optical element 14, thus effectively producing a squinting optical light source. This makes it possible to further improve the beam coincidence.

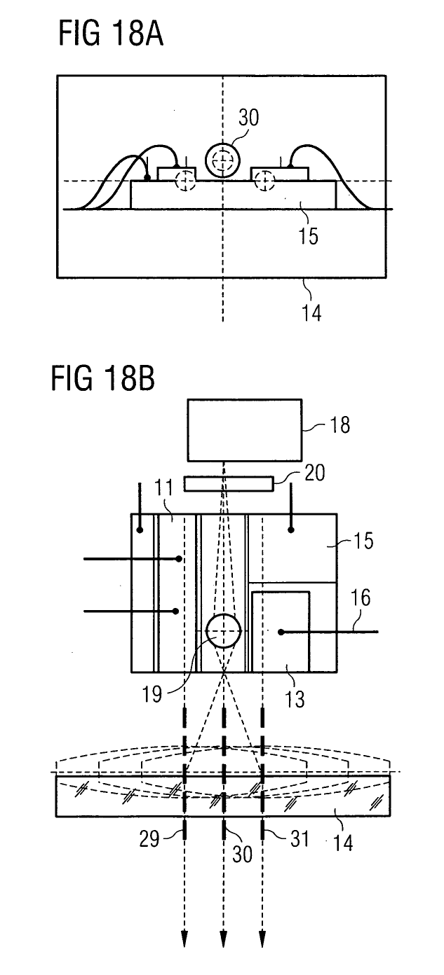

The embodiment illustrated in FIGS. 18A and 18B correspond essentially to the embodiment illustrated in FIGS. 16A and 16B, but with the optical light source containing only two edge-emitting semiconductor lasers instead of three edge-emitting semiconductor lasers, specifically a red semiconductor laser 11 and a blue semiconductor laser 13, and additionally a green semiconductor laser 18, which is not an edge-emitting laser and, in particular, is a frequency-doubled semiconductor laser 18. The embodiment and method of operation of the light source correspond to the embodiment shown in FIGS. 10A and 10B, and the embodiment and method of operation of the diffractive optical element which acts as a lens correspond to the embodiment in FIGS. 16A and 16B. It will, therefore, not be explained once again at this point.

The explanation of the invention on the basis of the embodiments should, of course, not be regarded as implying any restriction to these embodiments. In fact, the invention covers the disclosed features both individually and in every possible combination with one another, even if these combinations have not been stated explicitly in the claims.

We claim:

1. A beam combiner for a multicolor laser display, comprising an optical light source which has at least two semiconductor lasers with different wavelengths,
wherein the beam combiner has a lens, and
wherein the lens is arranged in a beam path which is formed by beams emitted from the at least two semiconductor lasers.

2. The beam combiner as claimed in claim 1,
wherein
the at least two semiconductor lasers have emission points which are at a distance of less than 500 μm from one another and/or from an optical axis of the lens.

3. The beam combiner as claimed in claim 2,
wherein
the at least two semiconductor lasers have emission points which are at a distance of less than 100 μm from one another and/or from an optical axis of the lens.

4. The beam combiner as claimed in claim 1,
wherein
the lens is arranged at a distance of 5 mm or less from the emission points of the semiconductor lasers.

5. The beam combiner as claimed in claim 1,
wherein
a prism is arranged in the beam path downstream from the lens.

6. The beam combiner as claimed in claim 1,
wherein
a birefringent plate is arranged in the beam path downstream from the lens.

7. The beam combiner as claimed in claim 1,
wherein
a further lens is arranged in the beam path downstream from the lens.

8. The beam combiner as claimed in claim 1,
wherein
a diffractive element is arranged in the beam path downstream from the lens.

9. The beam combiner as claimed in claim 1,
wherein
the lens is an achromatic lens.

10. The beam combiner as claimed in claim 1,
wherein
the lens has at least one free-form area.

11. The beam combiner as claimed in claim 1,
wherein
the lens is a diffractive optical element acting as a lens.

12. The beam combiner as claimed in claim 11,
wherein
the diffractive optical element has a plurality of optical axes, which are offset in the lateral direction with respect to one another, for the various wavelengths of the semiconductor lasers.

13. The beam combiner as claimed in claim 12,
wherein
the plurality of optical axes are offset in the lateral direction relative to one another such that the optical axis for one wavelength is in each case collinear with the emission direction of the semiconductor laser which emits this wavelength.

14. The beam combiner as claimed in claim 1,
wherein
the diffractive optical element has different optical axes, which are arranged at an angle to one another, for the various wavelengths of the semiconductor lasers.

15. The beam combiner as claimed in claim 1,
wherein
the at least two semiconductor lasers are arranged with mutually facing emission layers one above the other.

16. The beam combiner as claimed in claim 1,
wherein
the optical light source has three semiconductor lasers which are arranged with mutually facing emission layers in a triangle.

17. The beam combiner as claimed in claim 1,
wherein
the at least two semiconductor lasers are arranged alongside one another on a substrate.

18. The beam combiner as claimed in claim 1,
wherein
an emission point of at least one of the semiconductor lasers is arranged offset with respect to the emission point of the at least one other semiconductor laser in a direction which runs parallel to an optical axis of the lens.

19. The beam combiner as claimed in claim 1,
wherein
at least one of the semiconductor lasers is an edge-emitting laser diode.

20. The beam combiner as claimed in claim 1,
wherein
at least two of the semiconductor lasers are monolithically integrated on a substrate.

21. The beam combiner as claimed in claim 1,
wherein
at least one of the semiconductor lasers is a surface-emitting semiconductor laser.

22. The beam combiner as claimed in claim 21,
wherein
a spherical lens is arranged in the beam path of the surface-emitting semiconductor laser.

23. The beam combiner as claimed in claim 1,
wherein
at least one of the semiconductor lasers is a frequency-doubled semiconductor laser.

24. The beam combiner as claimed in claim 1,
wherein
the beam combiner has drive electronics for the semiconductor lasers, by means of which the semiconductor lasers can be driven with a time offset in order to achieve at least partial beam coincidence.

25. A multicolor laser display comprising a beam combiner as claimed in claim 1.

26. The multicolor laser display as claimed in claim 25,
wherein
the laser display has a scanner mirror for deflection onto a screen of the laser beams which are emitted by the at least two semiconductor lasers.
